(19) United States
(12) Patent Application Publication
(10) Pub. No.: US 2025/0255030 A1
(43) Pub. Date: Aug. 7, 2025

(54) OPTOELECTRONIC DEVICE AND METHOD FOR OPERATING AN OPTOELECTRONIC DEVICE

(71) Applicant: ams-OSRAM International GmbH, Regensburg (DE)

(72) Inventors: Zeljko PAJKIC, Regensburg (DE); Johann RAMCHEN, Hausen (DE); Michael MÜLLER, Pfaffenhofen (DE); Claus JÄGER, Regensburg (DE)

(21) Appl. No.: 18/855,957

(22) PCT Filed: Feb. 28, 2023
(86) PCT No.: PCT/EP2023/054913

§ 371 Date: Oct. 10, 2024

(30) Foreign Application Priority Data
Apr. 14, 2022 (DE) 10 2022 109 271.2

(51) Int. Cl. H10F 55/00; G02B 27/00; G02B 27/01; H01L 25/075; H01L 25/16; H10F 77/00

(52) U.S. Cl. CPC H10F 55/18; G02B 27/0093; G02B 27/0172; H01L 25/0753; H01L 25/167; H10F 77/933; G02B 2027/0138; G02B 2027/0178

(57) ABSTRACT

An optoelectronic device has a transparent carrier. The carrier has a two-dimensional arrangement of optoelectronic semiconductor chips. The optoelectronic semiconductor chips are electrically contacted by conductor tracks arranged on the carrier. At least some of the optoelectronic semiconductor chips are operable as light emitters in order to shine light at an eye. At least some of the optoelectronic semiconductor chips are operable as light receivers in order to detect light reflected at the eye.

The present invention relates to an optoelectronic device and to a method for operating an optoelectronic device.

This patent application claims the priority of the German patent application DE 10 2022 109 271.2, the disclosure content of which is incorporated herein by reference.

Optoelectronic devices for analyzing an eye are known from the prior art. Such devices may, for example, be used for access control. Eyeglasses with integrated optoelectronic devices are likewise known from the prior art.

It is an object of the present invention to provide an optoelectronic device. It is a further object of the present invention to specify a method for operating an optoelectronic device. These objects are achieved by an optoelectronic device and by a method for operating an optoelectronic device having the features of the independent patent claims. Various developments are specified in the dependent claims.

An optoelectronic device comprises a transparent carrier, which has a two-dimensional arrangement of optoelectronic semiconductor chips. The optoelectronic semiconductor chips are electrically contacted by conductive traces arranged on the carrier. At least some of the optoelectronic semiconductor chips can be operated as light emitters in order to shine light onto an eye. At least some of the optoelectronic semiconductor chips can be operated as light receivers in order to detect light reflected at the eye.

Advantageously, the optoelectronic semiconductor chips in this optoelectronic device are arranged directly on the transparent carrier. No additional installation space therefore needs to be reserved for the optoelectronic semiconductor chips in this optoelectronic device.

In one embodiment of the optoelectronic device, at least some of the optoelectronic semiconductor chips can be operated both as light emitters and as light receivers. This leads to a particularly simple structure of the optoelectronic device. Because at least some of the optoelectronic semiconductor chips can be operated both as light emitters and as light receivers, the optoelectronic device advantageously enables particularly flexible and versatile use.

In one embodiment of the optoelectronic device, the two-dimensional arrangement of optoelectronic semiconductor chips comprises a first two-dimensional arrangement of first optoelectronic semiconductor chips and a second two-dimensional arrangement of second optoelectronic semiconductor chips. The first optoelectronic semiconductor chips can be operated as light emitters. The second optoelectronic semiconductor chips can be operated as light receivers. In this variant of the optoelectronic device, the second optoelectronic semiconductor chips may be optimized for the detection of light so that a particularly reliable detection of light reflected at the eye is advantageously enabled.

In one embodiment of the optoelectronic device, the first two-dimensional arrangement and the second two-dimensional arrangement are superimposed with one another. Advantageously, this leads to a compact configuration of the optoelectronic device. Furthermore, particularly effective detection of the light reflected at the eye is therefore enabled for the second optoelectronic semiconductor chips of the second two-dimensional arrangement.

In one embodiment of the optoelectronic device, the second optoelectronic semiconductor chips comprise photodetector chips, in particular photodiode chips. Advantageously, such second optoelectronic semiconductor chips enable reliable detection of light reflected at the eye with a low power consumption.

In one embodiment of the optoelectronic device, the optoelectronic semiconductor chips comprise laser chips, in particular VCSEL chips. Advantageously, the optoelectronic semiconductor chips may in this case be configured with very compact external dimensions. Furthermore, such optoelectronic semiconductor chips make it possible to radiate light with a sufficiently high intensity onto an eye. One particular advantage may be that optoelectronic semiconductor chips configured as laser chips, in particular as VCSEL chips, may also enable operation as light receivers.

In one embodiment of the optoelectronic device, the optoelectronic semiconductor chips comprise LED chips. Advantageously, such optoelectronic semiconductor chips may also have compact external dimensions and may radiate light with a sufficient intensity onto an eye.

In one embodiment of the optoelectronic device, the optoelectronic semiconductor chips that can be operated as light emitters are configured to emit light in the near infrared spectral range, particularly in the spectral range between 780 nm and 2000 nm. Advantageously, the light emitted by the optoelectronic semiconductor chips is not visible to an eye in this case. A further advantage is that light from this spectral range is highly suitable for distinguishing various regions of an eye from one another. The intensity of the light may advantageously be dimensioned here so that there is no risk of damage to the illuminated eye.

In one embodiment of the optoelectronic device, neighboring optoelectronic semiconductor chips respectively have a spacing of between 50 μm and 1000 μm from one another. Advantageously, the two-dimensional arrangement of optoelectronic semiconductor chips appears invisible to an eye in this case.

In one embodiment of the optoelectronic device, all edges of all optoelectronic semiconductor chips have a length of less than 50 μm, in particular a length of less than 25 μm. Advantageously, the individual optoelectronic semiconductor chips of the two-dimensional arrangement are invisible to an eye in this case.

In one embodiment of the optoelectronic device, the conductive traces comprise ITO. Advantageously, the conductive traces may therefore be configured to be transparent and therefore invisible to an eye.

In one embodiment of the optoelectronic device, the optoelectronic device has a camera which is intended to detect light reflected at an eye. This also represents a possible way of detecting the light radiated onto an eye by the optoelectronic semiconductor chips and reflected at the eye.

In one embodiment of the optoelectronic device, the two-dimensional arrangement comprises between 2 and 200 optoelectronic semiconductor chips, in particular between 10 and 50 optoelectronic semiconductor chips. Advantageously, such a number of optoelectronic semiconductor chips enables precise and detailed analysis of an eye, and at the same time enables economical production and a space-saving design.

In one embodiment of the optoelectronic device, it is configured as a pair of eyeglasses, as a helmet or as a pair of binoculars. Advantageously, this makes it possible to arrange the optoelectronic device close to a user's eye without the user feeling it to be an impediment.

A method for operating an optoelectronic device of the type mentioned above comprises steps of shining light onto an eye by at least some of the optoelectronic semiconductor chips and of detecting an intensity of light reflected at the eye by at least some of the optoelectronic semiconductor chips. Advantageously, this method may take place without active interaction by the user of the optoelectronic device. For the user, this enables the method to be carried out without interfering with the user's everyday life.

In one embodiment of the method, the light is radiated by a plurality of optoelectronic semiconductor chips arranged at different positions. Advantageously, the eye is therefore illuminated from different directions, which enables particularly accurate and reliable analysis of properties of the eye.

In one embodiment of the method, the intensity of the reflected light is detected at a plurality of different positions. Advantageously, this makes it possible to detect light reflected at the eye in different directions so that particularly accurate and reliable analysis of the eye is enabled.

In one embodiment of the method, it is carried out repeatedly. At least one of the optoelectronic semiconductor chips is then operated alternately as a light emitter and as a light receiver. Advantageously, this makes it possible to illuminate the eye both from the position of this optoelectronic semiconductor chip and to detect light reflected in the direction of the position of this optoelectronic semiconductor chip.

In one embodiment of the method, it is carried out repeatedly. A time variation of the intensity of the reflected light is then recorded. Advantageously, this makes it possible to identify a time variation of a property of the eye, for example a change of a pupil size, a change of a viewing direction or a change of a state of opening of a lid of the eye.

In one embodiment of the method, a parameter of the eye, in particular a viewing direction of the eye, a size of a pupil of the eye or a state of opening of an eyelid of the eye, is derived from the intensity of the reflected light. This in turn may, for example, enable assessment of a user's concentration. For example, it may be possible to identify whether the user is averting their view or has closed their eye. This may, for example, be used for making safety-relevant decisions.

The above-described properties, features and advantages of this invention, as well as the way in which they are achieved, will become clearer and more easily understandable in connection with the following description of the exemplary embodiments, which will be explained in more detail in connection with the drawings, in which, respectively in a schematized representation,

FIG. 1 shows a perspective view of an optoelectronic device configured as a pair of eyeglasses;

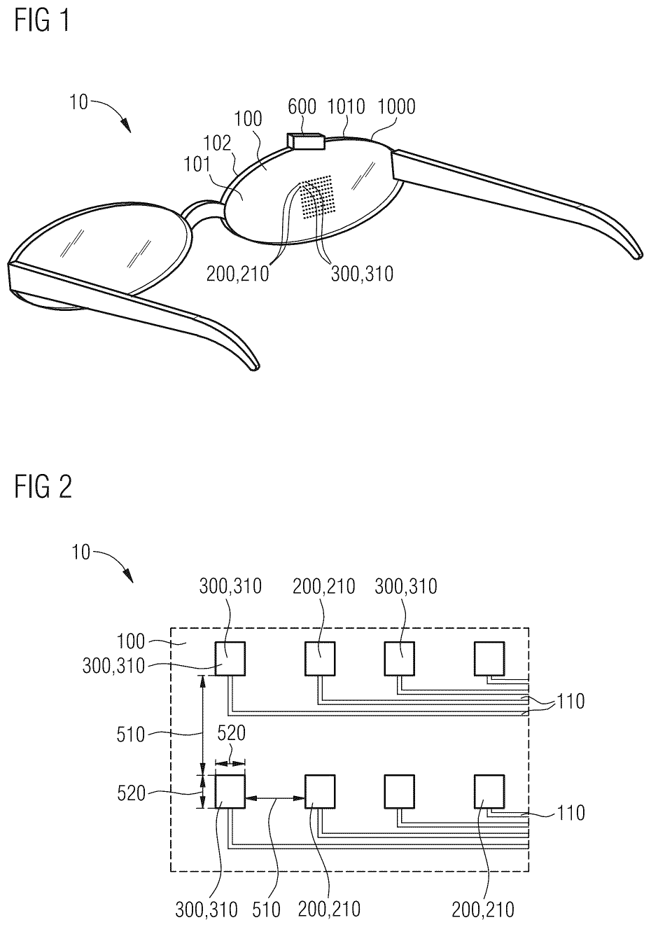

FIG. 2 shows a plan view of arrangements of optoelectronic semiconductor chips of the optoelectronic device;

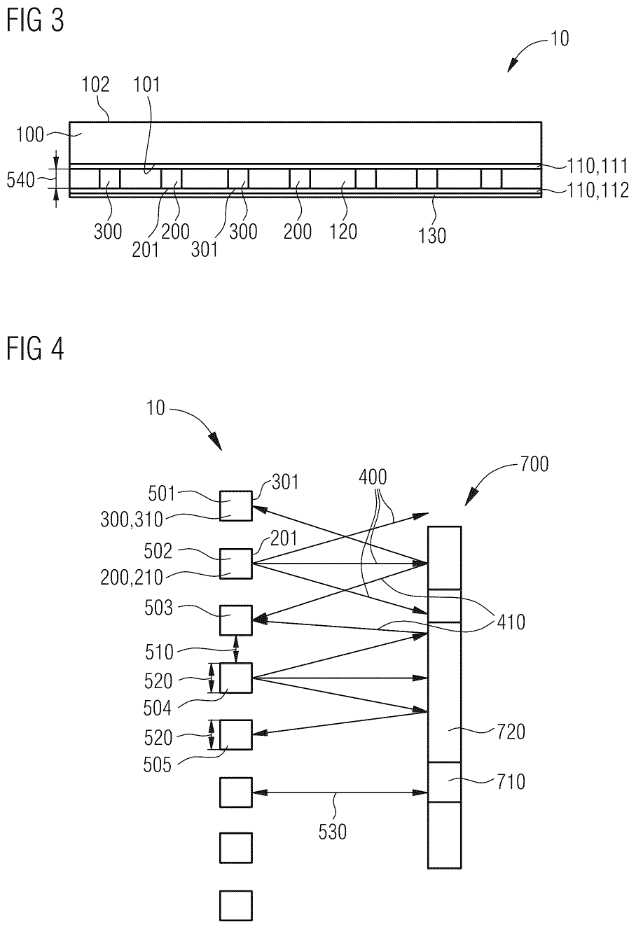

FIG. 3 shows a sectional side view of a part of the optoelectronic device;

FIG. 4 shows a side view of a part of the optoelectronic device and of an eye;

FIG. 5 shows the eye;

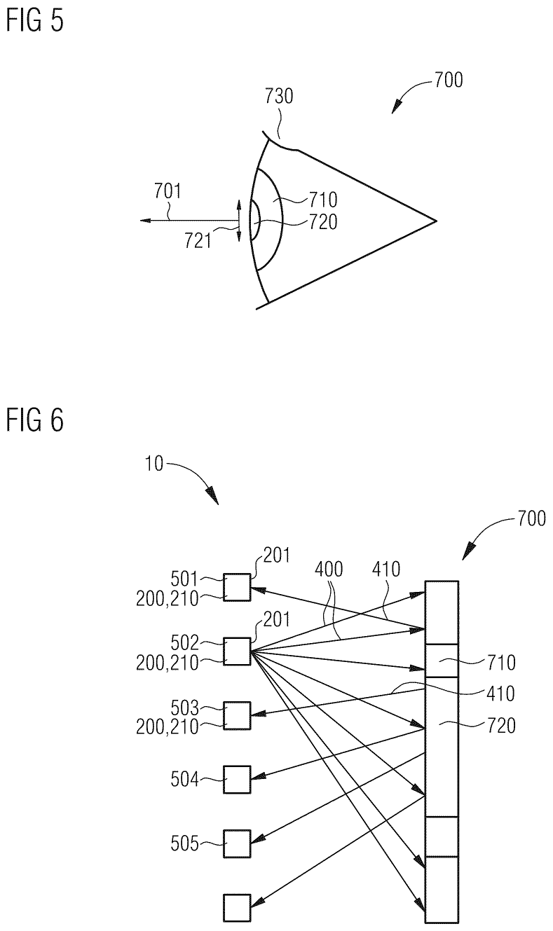

FIG. 6 shows a side view of a further variant of the optoelectronic device in a first operating state;

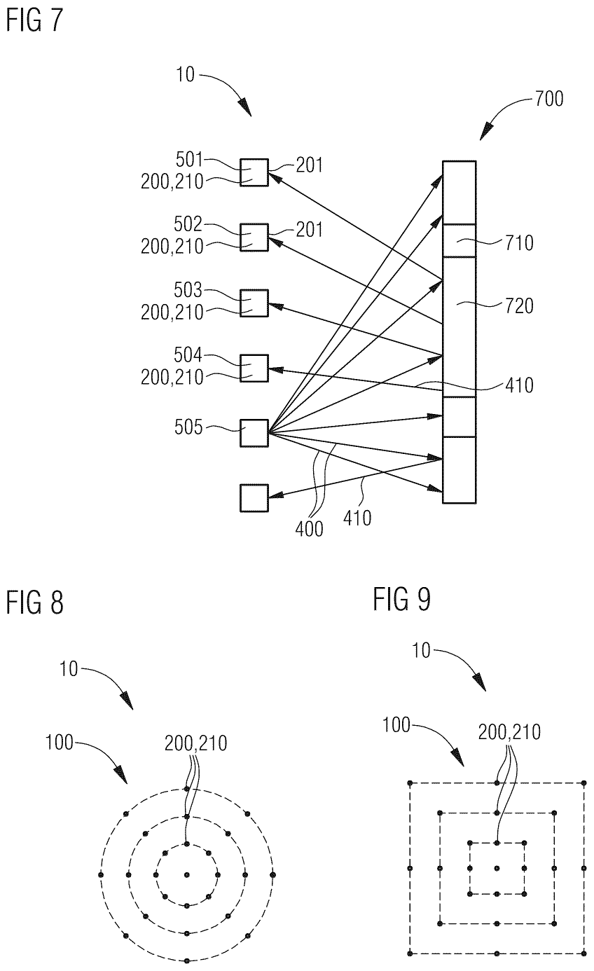

FIG. 7 shows a side view of the further variant of the optoelectronic device in a second operating state;

FIG. 8 shows one example of an arrangement of optoelectronic semiconductor chips;

FIG. 9 shows a further example of an arrangement of optoelectronic semiconductor chips;

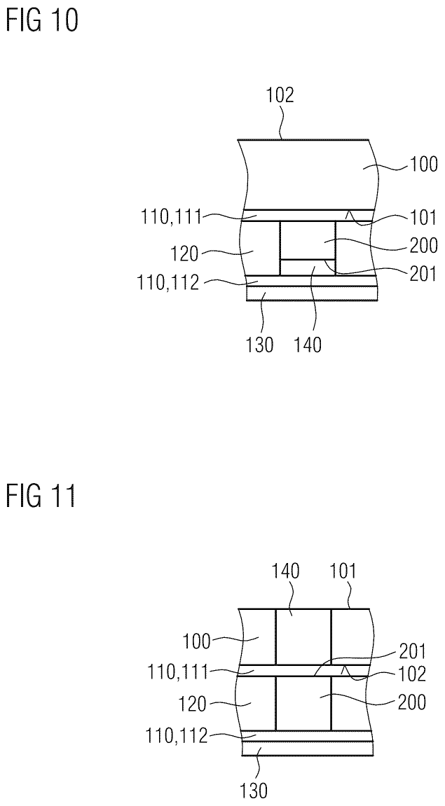

FIG. 10 shows a part of one variant of the optoelectronic device;

FIG. 11 shows a part of a further variant of the optoelectronic device;

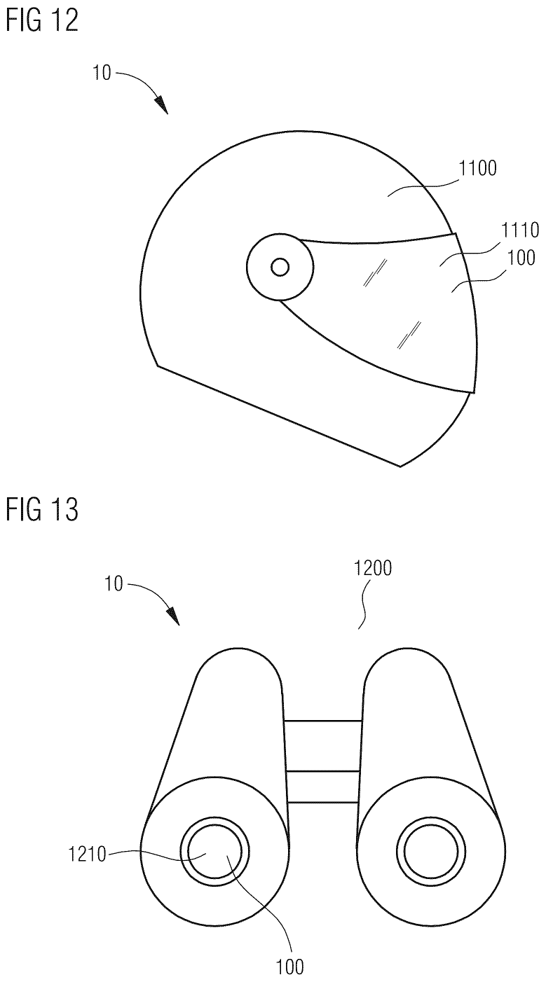

FIG. 12 shows an optoelectronic device configured as a helmet; and

FIG. 13 shows an optoelectronic device configured as a pair of binoculars.

FIG. 1 shows a schematic perspective view of an optoelectronic device 10. In the example represented, the optoelectronic device 10 is configured as a pair of eyeglasses 1000. The eyeglasses 1000 may for example be corrective eyeglasses, sunglasses or protective glasses, and are intended to be worn by a human user of the optoelectronic device 10.

The optoelectronic device 10 has a transparent carrier 100. In the example of the optoelectronic device 10 configured as a pair of eyeglasses 1000, the transparent carrier 100 is formed by an eyeglass lens 1010 of the eyeglasses 1000. The carrier 100 may for example comprise a mineral glass or a plastic, for example a polycarbonate. The carrier 100 has a first side 101, which is oriented toward an eye of the user during use of the optoelectronic device 10. A second side 102 of the carrier 100, opposite to the first side 101, faces away from the eye of the user during use of the optoelectronic device 10.

The carrier 100 of the optoelectronic device 10 has a first two-dimensional arrangement 210 of first optoelectronic semiconductor chips 200. The carrier 100 furthermore has a second two-dimensional arrangement 310 of second optoelectronic semiconductor chips 300. The first two-dimensional arrangement 210 and the second two-dimensional arrangement 310 are arranged in the same region of the carrier 100 and are superimposed with one another. This means that at least some first optoelectronic semiconductor chips 200 are arranged between second optoelectronic semiconductor chips 300, and vice versa. The first two-dimensional arrangement 210 of first optoelectronic semiconductor chips 200 and the second two-dimensional arrangement 310 of second optoelectronic semiconductor chips 300 together likewise form a two-dimensional arrangement of optoelectronic semiconductor chips.

FIG. 2 shows a schematic plan view of a part of the first two-dimensional arrangement 210 and of the second two-dimensional arrangement 310. FIG. 3 shows a schematic sectional side view of a part of the carrier 100 with a portion of the first two-dimensional arrangement 210 and a portion of the second two-dimensional arrangement 310.

In the example shown in FIGS. 1 to 3, the first two-dimensional arrangement 210 and the second two-dimensional arrangement 310 are configured as mutually offset matrix arrangements of rows and columns. First optoelectronic semiconductor chips 200 and second optoelectronic semiconductor chips 300 alternate in each row here. All rows of the arrangement are configured identically. The number of first optoelectronic semiconductor chips 200 corresponds to the number of second optoelectronic semiconductor chips 300. This configuration of the first two-dimensional arrangement 210 and of the second two-dimensional arrangement 310 is, however, purely exemplary. Other arrangements are possible, and the number of first optoelectronic semiconductor chips 200 need not correspond to the number of second optoelectronic semiconductor chips 300.

In the example shown in FIGS. 1 to 3, the first optoelectronic semiconductor chips 200 and the second optoelectronic semiconductor chips 300 are arranged on the first side 101 of the carrier 100. It is, however, also possible to arrange the first optoelectronic semiconductor chips 200 and the second optoelectronic semiconductor chips 300 on the second side 102 of the carrier 100 or to embed them in the material of the carrier 100.

The first optoelectronic semiconductor chips 200 and the second optoelectronic semiconductor chips 300 are arranged between a first conductive trace plane 111 and a second conductive trace plane 112, which respectively form conductive traces 110 via which the first optoelectronic semiconductor chips 200 and the second optoelectronic semiconductor chips 300 are electrically contacted. For example, one of the conductive trace planes 111, 112 may be structured in such a way that it respectively has individual conductive traces 110 for each of the first optoelectronic semiconductor chips 200 and second optoelectronic semiconductor chips 300, while the other conductive trace plane 111, 112 forms a common reference potential for all first optoelectronic semiconductor chips 200 and second optoelectronic semiconductor chips 300. The first conductive trace plane 111 and the second conductive trace plane 112 expediently comprise an optically transparent and electrically conductive material, for example ITO or a polymer.

The first optoelectronic semiconductor chips 200 and second optoelectronic semiconductor chips 300 arranged between the first conductive trace plane 111 and the second conductive trace plane 112 are embedded in a transparent dielectric 120, for example a spin-on glass (SOG), an epoxide, a silicone or a low-melting glass.

In the example represented, a transparent protective layer 130 is arranged on the side of the arrangement of optoelectronic semiconductor chips 200, 300 and conductive trace planes 111, 112 facing away from the carrier 100, although it may also be omitted. The protective layer 130 may for example comprise a scratch-proof material, for example SiO₂ or SiN.

In a thickness direction measured perpendicularly with respect to the first side 101 of the carrier 100, the first optoelectronic semiconductor chips 200 and the second optoelectronic semiconductor chips 300 have a thickness 540 which may lie for example between 2 μm and 10 μm. The thicknesses of the conductive trace planes 111, 112 and of the protective layer 130 may, for example, each be less than 1 μm.

In a direction measured parallel to the first side 101 of the carrier 100, the edges of all first optoelectronic semiconductor chips 200 and all second optoelectronic semiconductor chips 300 have edge lengths 520. It is expedient for the edge lengths 520 to be less than 50 μm, in particular less than 25 μm. The edge lengths 520 may, for example, lie between 5 μm and 25 μm. This ensures that the first optoelectronic semiconductor chips 200 and the second optoelectronic semiconductor chips 300 are not visible to a user of the optoelectronic device 10.

The individual optoelectronic semiconductor chips 200, 300 of the first two-dimensional arrangement 210 and of the second two-dimensional arrangement 310 have spacings from one another which correspond to at least one chip spacing 510. It is expedient for the chip spacing 510 to be at least ten times as great as the edge length 520, and for example to lie between 50 μm and 1000 μm. This also ensures that all the first optoelectronic semiconductor chips 200 of the first two-dimensional arrangement 210 and the second optoelectronic semiconductor chips 300 of the second two-dimensional arrangement 310 are not visible to a user of the optoelectronic device 10.

FIG. 4 shows a schematic sectional side view of a part of the optoelectronic device 10 during use of the optoelectronic device 10. A user of the optoelectronic device 10 wears the optoelectronic device 10, configured for example as a pair of eyeglasses 1000, so that the first side 101 of the carrier 100 faces toward an eye 700 of the user and the first two-dimensional arrangement 210 of first optoelectronic semiconductor chips 200 and the second two-dimensional arrangement 310 of second optoelectronic semiconductor chips 300 are arranged in front of the eye 700 of the user. The first optoelectronic semiconductor chips 200 and the second optoelectronic semiconductor chips 300 have in this case an eye distance 530 from the eye 700. It is expedient for the eye distance 530 to be between 5 mm and 50 mm. For example, the eye distance 530 may be about 10 mm.

Each first optoelectronic semiconductor chip 200 has a front side 201, which is oriented toward the eye 700. Each second optoelectronic semiconductor chip 300 has a front side 301, which is oriented toward the eye 700.

The first optoelectronic semiconductor chips 200 may be operated as light emitters in order to radiate light 400 onto the eye 700. The radiated light 400 is emitted on the front sides 201 of the first optoelectronic semiconductor chips 200. The radiated light 400 may for example have a wavelength in the near infrared spectral range, for example a wavelength of between 780 nm and 2000 nm. The wavelength and the intensity of the light 400 radiated by the first optoelectronic semiconductor chips 200 are dimensioned so that the eye 700 experiences no damage.

The first optoelectronic semiconductor chips 200 may for example be configured as laser chips, for example as VCSEL chips. The first optoelectronic semiconductor chips 200 may, however, also be configured for example as light-emitting diode chips (LED chips). It is also possible for different first optoelectronic semiconductor chips 200 to be configured differently.

The second optoelectronic semiconductor chips 300 may be operated as light receivers in order to detect light 410 reflected at the eye 700. For this purpose, the second optoelectronic semiconductor chips 300 may record light 410 which is reflected at the eye 700 and impinges on the front sides 301 of the second optoelectronic semiconductor chips 300. The second optoelectronic semiconductor chips 300 are then configured to record light with a wavelength that corresponds to the wavelength of the light 400 radiated by the first optoelectronic semiconductor chips 200. Light 400 radiated by the first optoelectronic semiconductor chips 200 of the optoelectronic device 10 can therefore be reflected at the eye 700 and detected as reflected light 410 by the second optoelectronic semiconductor chips 300. It is expedient for each second optoelectronic semiconductor chip 300 to be able to quantitatively determine the intensity of the light impinging on its front side 301.

The second optoelectronic semiconductor chips 300 may for example be configured as photodetector chips, in particular for example as photodiode chips.

FIG. 5 shows a schematic representation of the eye 700 of the user of the optoelectronic device 10. The eye 700 has an iris 710, which encloses a pupil 720. The pupil 720 has a variable size 721. The eye 700 can be covered by an eyelid 730. A viewing direction 701 of the eye 700 can be changed by a movement of the eye 700, which is associated with a movement of the iris 710 and of the pupil 720.

The viewing direction 701 of the eye 700, the size 721 of the pupil 720 and the state of opening of the eyelid 730 represent examples of parameters of the eye 700 that may be ascertainable by the optoelectronic device 10. The recording of these parameters may for example take place for safety reasons, for example while the user of the optoelectronic device 10 is driving a vehicle or another machine, for example in order to ensure that the user is concentrating sufficiently on this activity.

The various first optoelectronic semiconductor chips 200 of the first two-dimensional arrangement 210 and second optoelectronic semiconductor chips 300 of the second two-dimensional arrangement 310 are arranged at different positions. In the schematically represented example of FIG. 4, one of the second optoelectronic semiconductor chips 300 is arranged at a first position 501. Further second optoelectronic semiconductor chips 300 are arranged at a third position 503 and at a fifth position 505. First optoelectronic semiconductor chips 200 are respectively arranged at a second position 502 and at a fourth position 504.

The intensity of the light 410 reflected to a specific second optoelectronic semiconductor chip 300 depends on the position 501, 503, 505 of this second optoelectronic semiconductor chip 300, on the positions 502, 504 of the light-emitting first optoelectronic semiconductor chips 200 and also on parameters of the eye 700 reflecting the radiated light 400, for example the viewing direction 701, the size 721 of the pupil 720 and the state of opening of the eyelid 730. The iris 710, the pupil 720, the other portions of the eye 700 and the eyelid 730 each have different reflection properties. The intensity of the reflected light 410 reaching a particular second optoelectronic semiconductor chip 300 may therefore vary in the event of a change of the viewing direction 701, the size 721 of the pupil 720 or the state of opening of the eyelid 730.

This makes it possible to determine the aforementioned parameters of the eye 700 by a method for operating the optoelectronic device 10. Light 400 radiated by the first optoelectronic semiconductor chips 200 is in this case shone onto the eye 700 of the user of the optoelectronic device 10. The light 410 reflected at the eye 700 is detected by the second optoelectronic semiconductor chips 300. One or more parameters of the eye 700, for example the viewing direction 701, the size 721 of the pupil 720 or the state of opening of the eyelid 730, are derived from the intensity of the reflected light 410.

It is expedient for the radiated light 400 to be emitted by a plurality of first optoelectronic semiconductor chips 200 arranged at different positions 502, 504. A plurality of first optoelectronic semiconductor chips 200 may radiate light 400 simultaneously here. It is, however, also possible for different first optoelectronic semiconductor chips 200 to radiate light 400 chronologically in succession.

It is likewise expedient for the reflected light 410, in particular the intensity of the reflected light 410, to be detected by second optoelectronic semiconductor chips 300 arranged at different positions 501, 503, 505. Second optoelectronic semiconductor chips 300 arranged at different positions 501, 503, 505 may detect the light 410 reflected to them simultaneously or chronologically in succession here.

It is expedient to carry out the method repeatedly while ascertaining a time variation of the intensities of the reflected light 410 that are recorded by one or more second optoelectronic semiconductor chips 300. Time variations of the parameters of the eye 700 may be identified in this way.

FIGS. 6 and 7 show schematic views of an alternative variant of the optoelectronic device 10 in two chronologically successive operating states.

In the variant shown in FIGS. 6 and 7, only the first optoelectronic semiconductor chips 200 of the first two-dimensional arrangement 210 are present. The second optoelectronic semiconductor chips 300 of the second two-dimensional arrangement 310 are omitted. Instead, in this variant of the optoelectronic device 10 at least some of the first optoelectronic semiconductor chips 200 can be operated both as light emitters and as light receivers. During operation as light emitters, the relevant first optoelectronic semiconductor chips 200 radiate light 400 on their front sides 201 onto the eye 700. During operation as light receivers, the relevant first optoelectronic semiconductor chips 200 detect light 410 reflected at the eye 700 which impinges on the front sides 201 of the first optoelectronic semiconductor chips 200. It is particularly expedient for the relevant first optoelectronic semiconductor chips 200 to be operable chronologically in alternation either as light emitters or as light receivers.

The first optoelectronic semiconductor chips 200 that can be operated both as light emitters and as light receivers may for example be configured as laser chips, in particular for example as VCSEL chips.

The variant of the optoelectronic device 10 as shown in FIGS. 6 and 7 may, for example, be operated so that at least one of the first optoelectronic semiconductor chips 200 is operated alternately as a light emitter and as a light receiver. In the operating state shown in FIG. 6, the first optoelectronic semiconductor chip 200 arranged at the second position 502 is operated as a light emitter and radiates light 400 onto the eye 700. The first optoelectronic semiconductor chips 200 arranged at the first position 501, the third position 503, the fourth position 504 and the fifth position 505 are operated as light receivers and detect light 410 reflected at the eye 700. In the operating state of the optoelectronic device 10 as shown in FIG. 7, the first optoelectronic semiconductor chip 200 arranged at the fifth position 505 is operated as a light emitter and radiates light 400 toward the eye 700. The first optoelectronic semiconductor chips 200 arranged at the first position 501, the second position 502, the third position 503 and the fourth position 504 are operated as light receivers and detect light 410 reflected at the eye 700.

Depending on the parameters of the eye 700 that are to be ascertained, different subsets of the first optoelectronic semiconductor chips 200 may be operated in the course of time as light emitters and as light receivers in a different geometrical arrangement.

The edge lengths and spacings of the first optoelectronic semiconductor chips 200 may be dimensioned in the variant shown in FIGS. 6 and 7 as in the variant of FIGS. 1 to 4.

FIG. 8 shows a schematic plan view of an alternative configuration of the first two-dimensional arrangement 210 of first optoelectronic semiconductor chips 200. In the example shown in FIG. 8, the first optoelectronic semiconductor chips 200 are arranged on concentric rings. In the example shown here, 3 concentric rings with 8 first optoelectronic semiconductor chips 200 per ring are provided. A further first optoelectronic semiconductor chip 200 is located at the center of the first two-dimensional arrangement 210.

If a second two-dimensional arrangement 310 of second optoelectronic semiconductor chips 300 is also present, the second two-dimensional arrangement 310 could be configured like the first two-dimensional arrangement 210 but rotated relative thereto by a fixed angle. Either a first optoelectronic semiconductor chip 200 or a second optoelectronic semiconductor chip 300 is then present at the central position. Another second two-dimensional arrangement 310 is also possible.

FIG. 9 shows a further exemplary alternative of a possible first two-dimensional arrangement 210 of first optoelectronic semiconductor chips 200 in a schematic plan view. In the first two-dimensional arrangement 210 as shown in FIG. 9, the first optoelectronic semiconductor chips 200 lie on the corners and side midpoints of concentrically arranged squares. In the example represented, 3 squares with 8 first optoelectronic semiconductor chips 200 each are provided. A further first optoelectronic semiconductor chip 200 is located at the center of the first two-dimensional arrangement 210.

If a second two-dimensional arrangement 310 of second optoelectronic semiconductor chips 300 is also present, the second two-dimensional arrangement 310 could for example be configured like the first two-dimensional arrangement 210 but displaced laterally relative thereto by a fixed amount. Another second two-dimensional arrangement 310 is also possible.

The optoelectronic device 10 may for example have between 2 and 100 first optoelectronic semiconductor chips 200, in particular for example between 10 and 50 first optoelectronic semiconductor chips 200. If the optoelectronic device 10 also has second optoelectronic semiconductor chips 300, their number may have a similar value and may in particular correspond to the number of first optoelectronic semiconductor chips 200.

In a further variant of the optoelectronic device 10, it has only first optoelectronic semiconductor chips 200. These only need to be configured for operation as light emitters. In addition, the optoelectronic device 10 in this variant has a camera 600, which is represented schematically in FIG. 1. The camera 600 is intended to detect the light 410 reflected at the eye 700 of the user of the optoelectronic device 10. The camera 600 may, for example, comprise a CCD sensor. In addition, the camera 600 may have optics. It is expedient for the camera 600 to be arranged in a peripheral region or outside the transparent carrier 100 so that the camera 600 does not limit the field of view of a user of the optoelectronic device 10. Of course, both the second two-dimensional arrangement 310 of second optoelectronic semiconductor chips 300 and the camera 600 may also be present.

FIG. 10 shows a schematic sectional side view of a detail of a further variant of the optoelectronic device 10. A portion of the carrier 100 with the first side 101 and the second side 102, a portion of the first conductive trace plane 111 arranged on the first side 101 of the carrier 100, one of the first optoelectronic semiconductor chips 200 arranged on the first conductive trace plane 111 with a part of the surrounding dielectric 120, a part of the second conductive trace plane 112 and a part of the protective layer 130 are represented.

In contrast to the variant of the optoelectronic device 10 explained with the aid of FIG. 3, in the variant of the optoelectronic device 10 as shown in FIG. 10 an optical element 140 is arranged on the front side 201 of the first optoelectronic semiconductor chip 200 and is embedded together with the first optoelectronic semiconductor chip 200 in the dielectric 120. Corresponding optical elements 140 may be arranged on the front sides 201 of the further first optoelectronic semiconductor chips 200. The optical element 140 may, for example, have an imaging property. In this case, the optical element 140 may for example be configured as an optical lens or as a meta-optical element. The optical element 140 may also have a wavelength-converting property and be intended to convert light emitted by the first optoelectronic semiconductor chip 200 at least partially into light with a different wavelength.

In addition or as an alternative, optical elements may also be arranged on the front sides 301 of the second optoelectronic semiconductor chips 300 if a second two-dimensional arrangement 310 of second optoelectronic semiconductor chips 300 is present.

FIG. 11 shows a schematic sectional side view of a part of a further variant of the optoelectronic device 10. A portion of the carrier 100 with the first side 101 oriented toward the eye 700 of the user of the optoelectronic device 10 and the second side 102 opposite to the first side 101 are represented. A portion of the first conductive trace plane 111 and a portion of the second conductive trace plane 112 as well as one of the first optoelectronic semiconductor chips 200 arranged between the first conductive trace plane 111 and the second conductive trace plane 112, and a part of the dielectric 120 embedding the first optoelectronic semiconductor chips 200 are likewise represented. A part of the protective layer 130 covering the second conductive trace plane 112 is furthermore represented, although this may be omitted.

In contrast to the variant of the optoelectronic device 10 explained with the aid of FIG. 3, in the variant of the optoelectronic device 10 as shown in FIG. 11 the conductive trace planes 111, 112, the first optoelectronic semiconductor chips 200, the dielectric 120 and the protective layer 130 are arranged on the second side 102 of the transparent carrier 100, which faces away from the eye 700 of the user. The front sides 201 of the first optoelectronic semiconductor chips 200 and the front sides 301 of second optoelectronic semiconductor chips 300, which are likewise present, are oriented toward the carrier 100. Light 400 radiated by the first optoelectronic semiconductor chips 200 on the front sides 201 is therefore radiated through the carrier 100 in the direction of the eye 700. Light 410 reflected at the eye 700 travels through the carrier 100 back to the first optoelectronic semiconductor chips 200 operated as light receivers, or second optoelectronic semiconductor chips 300.

A portion of the carrier 100, through which light 400 radiated by the first optoelectronic semiconductor chip 200 shines, is configured in the variant of the optoelectronic device 10 as shown in FIG. 11 as an optical element 140. Corresponding optical elements 140 may be formed in the carrier 100 over the front sides 201 of the further first optoelectronic semiconductor chips 200. Portions of the carrier 100 may also be configured as optical elements 140 over the front sides 301 of optionally present optoelectronic semiconductor chips 300.

The optical element 140 may for example be an imaging optical element, and may for example be configured as a meta-optical element. The optical element 140 may also have a wavelength-converting property.

FIG. 12 shows a schematic representation of an alternative variant of the optoelectronic device 10. In the variant shown in FIG. 12, the optoelectronic device 10 is configured as a helmet 1100, for example as a motorcycle helmet. The transparent carrier 100 of the optoelectronic device 10 is formed by a helmet visor 1110 of the helmet 1100. In other regards, the variant of the optoelectronic device 10 as shown in FIG. 12 may be configured as described above with the aid of FIGS. 1 to 11.

FIG. 13 shows a schematic representation of a further variant of the optoelectronic device 10. In the variant shown in FIG. 13, the optoelectronic device 10 is configured as a pair of binoculars 1200. The transparent carrier 100 of the optoelectronic device 10 is formed by an eyepiece 1210 of the binoculars 1200. In other regards, the variant of the optoelectronic device 10 as shown in FIG. 13 may be configured as described above with the aid of FIGS. 1 to 11.

### List of Reference Sings

10 optoelectronic device
100 carrier
101 first side
102 second side
110 conductive trace
111 first conductive trace plane
112 second conductive trace plane
120 dielectric
130 protective layer
140 optical element
200 first optoelectronic semiconductor chip
201 front side
210 first two-dimensional arrangement
300 second optoelectronic semiconductor chip
301 front side
310 second two-dimensional arrangement
400 radiated light
410 reflected light
501 first position
502 second position
503 third position
504 fourth position
505 fifth position
510 chip spacing
520 edge length
530 eye distance
540 thickness
600 camera
700 eye
701 viewing direction
710 iris
720 pupil
721 size of the pupil
730 eyelid
1000 eyeglasses
1010 eyeglass lens
1100 helmet
1110 helmet visor
1200 binoculars
1210 eyepiece

1. An optoelectronic device,
having a transparent carrier,
wherein the carrier has a two-dimensional arrangement of optoelectronic semiconductor chips,
wherein the optoelectronic semiconductor chips are electrically contacted by conductive traces arranged on the carrier,
wherein at least some of the optoelectronic semiconductor chips can be operated as light emitters in order to shine light onto an eye,
wherein at least some of the optoelectronic semiconductor chips can be operated as light receivers in order to detect light reflected at the eye, and
wherein at least some of the optoelectronic semiconductor chips can be operated both as light emitters and as light receivers.

2-5. (canceled)

6. The optoelectronic device according to claim 1,
wherein the optoelectronic semiconductor chips comprise laser chips, in particular VCSEL chips.

7. The optoelectronic device according to claim 1,
wherein the optoelectronic semiconductor chips comprise LED chips.

8. The optoelectronic device according to claim 1,
wherein the optoelectronic semiconductor chips that can be operated as light emitters are configured to emit light in the near infrared spectral range, particularly in the spectral range between 780 nm and 2000 nm.

9. The optoelectronic device according to claim 1,
wherein neighboring optoelectronic semiconductor chips respectively have a spacing of between 50 μm and 1000 μm from one another.

10. The optoelectronic device according to claim 1,
wherein all edges of all optoelectronic semiconductor chips have a length of less than 50 μm, in particular a length of less than 25 μm.

11. The optoelectronic device according to claim 1,
wherein the conductive traces comprise ITO.

12. The optoelectronic device according to claim 1,
wherein the optoelectronic device has a camera which is intended to detect light reflected at an eye.

13. The optoelectronic device according to claim 1,
wherein the two-dimensional arrangement comprises between 2 and 200 optoelectronic semiconductor chips, in particular between 10 and 50 optoelectronic semiconductor chips.

14. The optoelectronic device according to claim 1,
wherein the optoelectronic device is configured as a pair of eyeglasses, as a helmet or as a pair of binoculars.

15. A method for operating an optoelectronic device,
wherein the optoelectronic device is configured according to claim 1, and the method has the following steps:
shining light onto an eye by at least some of the optoelectronic semiconductor chips; and
detecting an intensity of light reflected at the eye by at least some of the optoelectronic semiconductor chips,
wherein the method is carried out repeatedly, and
wherein at least one of the optoelectronic semiconductor chips is operated alternately as a light emitter and as a light receiver.

16. The method according to claim 15,
wherein the light is radiated by a plurality of optoelectronic semiconductor chips arranged at different positions.

17. The method according to claim 15,
wherein the intensity of the reflected light is detected at a plurality of different positions.

18. (canceled)

19. The method according to claim 15,
wherein a time variation of the intensity of the reflected light is recorded.

20. The method according to claim 15,
wherein a parameter of the eye, in particular a viewing direction of the eye, a size of a pupil of the eye or a state of opening of an eyelid of the eye, is derived from the intensity of the reflected light.

21. An optoelectronic device,
having a transparent carrier,
wherein the carrier has a two-dimensional arrangement of optoelectronic semiconductor chips,
wherein the optoelectronic semiconductor chips are electrically contacted by conductive traces arranged on the carrier,
wherein at least some of the optoelectronic semiconductor chips can be operated as light emitters in order to shine light onto an eye, and
wherein at least some of the optoelectronic semiconductor chips can be operated as light receivers in order to detect light reflected at the eye.

22. The optoelectronic device according to claim 21,
wherein the two-dimensional arrangement of optoelectronic semiconductor chips comprises a first two-dimensional arrangement of first optoelectronic semiconductor chips and a second two-dimensional arrangement of second optoelectronic semiconductor chips,
wherein the first optoelectronic semiconductor chips can be operated as light emitters, and
wherein the second optoelectronic semiconductor chips can be operated as light receivers.

23. The optoelectronic device according to claim 22,
wherein the first two-dimensional arrangement and the second two-dimensional arrangement are superimposed with one another.

24. The optoelectronic device according to claim 22,
wherein the second optoelectronic semiconductor chips comprise photodetector chips, in particular photodiode chips.
